(19) United States
(12) Patent Application Publication
(10) Pub. No.: US 2010/0018677 A1
(43) Pub. Date: Jan. 28, 2010

(54) HEAT PIPE STRUCTURE AND THERMAL DISSIPATION SYSTEM APPLYING THE SAME

(75) Inventor: Yao-Shih Leng, Taipei City (TW)

Correspondence Address: APEX JURIS, PLLC, 12733 LAKE CITY WAY NORTHEAST, SEATTLE, WA, 98125, US

(73) Assignee: MICRO-STAR INTERNATIONA'L CO., LTD., Jung-He City (TW)

(21) Appl. No.: 12/253,190

(22) Filed: Oct. 16, 2008

(30) Foreign Application Priority Data
Jul. 25, 2008 (TW) 097213327

(51) Int. Cl. F28D 15/00; H05K 7/20

(52) U.S. Cl. 165/104.26; 165/104.33; 361/700

(57) ABSTRACT

A heat pipe structure and a thermal dissipation system applying the same are described. The heat pipe structure includes a pipe component and a magnetic means, the pipe component has a working fluid, and the magnetic means is disposed on an external part of the pipe component to magnetize the working fluid, thus accelerating a backflow speed of the working fluid. The magnetic means is controlled by a sensing element, such that the magnetic means is driven to function according to a working temperature of the heat source, thereby improving the thermal transfer efficiency.

### CROSS-REFERENCE TO RELATED APPLICATIONS

This non-provisional application claims priority under 35 U.S.C. § 119(a) on Patent Application No(s). 097213327 filed in Taiwan, R.O.C. on Jul. 25, 2008 the entire contents of which are hereby incorporated by reference.

### BACKGROUND OF THE INVENTION

2. Field of Invention

The present invention relates to a thermal exchanging equipment, and more particularly to a heat pipe structure and a thermal exchanging system applying the heat pipe structure.

2. Related Art

For example, a computer system has two main electronic devices, namely, a central processing unit (CPU) for performing logic operation, and a graphics processing unit (GPU) for performing image processing and displaying. In order to make the CPU, the GPU, or other electronic devices maintain the normal operation, it is necessary to effectively dissipate the thermal generated by the electronic devices during operation. For the common thermal dissipation manner, a heat sink made of a metal material such as aluminum and copper is adhered to the electronic device, the heat sink has a plurality of fins, and a fan is installed on the fins. The thermal generated by the electronic device during operation is transferred to the fins of the heat sink, the fan introduces a cold air flow from the external to perform a thermal exchange with the fins, and dissipate the hot air to the outside. Since the thermal generated from the CPU or the GPU increases as the working frequency is enhanced, and the volume of the heat sink cannot be enlarged due to the limited volume of the product, the thermal dissipation technique adopting a heat pipe is widely applied to the computer system in order to improve the thermal dissipation efficiency with the limited volume.

The existing heat pipe has a sealed elongated pipe body made of copper, a capillary structure is disposed on an inner wall of the pipe body, and an appropriate amount of working fluid is filled in the pipe body. One end of the heat pipe is an evaporating end, and the other end is a condensing end. The evaporating end is adhered to the heat source. The working fluid in the pipe body achieves a boiling point after being heated, so as to be vaporized and evaporated. The evaporated gas moves towards the condensing end of the pipe body, the gas contacts with the inner wall of the pipe body at the condensing end to release the heat. The gas returns to the liquid after releasing the heat, the liquid is adhered to the pipe wall and then flows back to the evaporating end through the capillary structure disposed on the inner wall of the pipe body, thus forming a natural circulating thermal dissipation system.

However, the heat pipe has five limits, namely, capillary limit, boiling limit, sonic limit, entrainment limit, and viscous limit. For the capillary limit, the working fluid at the condensing end has to have enough force to overcome the gravity and the flowing resistance, so as to flow back to the evaporating end to absorb the heat, and the force mainly comes from the capillary force generated from the capillary structure to assist the backflow. When the capillary force may not overcome the gravity and the pressure loss resulting from flowing, the working fluid may not continuously flow back to the evaporating end, thereby greatly reducing the thermal transfer efficiency. Definitely, the obstacle may be reduced by changing the capillary structure design, but it is difficult to manufacture or process the capillary structure of the heat pipe, such that the application of the heat pipe is limited in a certain degree.

### SUMMARY OF THE INVENTION

When the working fluid of the recently known heat pipe flows back from the condensing end to the evaporating end, if the backflow of the working fluid is obstructed, the thermal transfer efficiency is affected. Therefore, the present invention provides a heat pipe structure capable of improving the thermal transfer efficiency, and a thermal dissipation system applying the heat pipe structure.

The heat pipe structure according to the present invention includes a pipe component and a magnetic means. The magnetic means is disposed on an external part of the pipe component, in which the magnetic means generates a magnetic field to magnetize a working fluid in the pipe component, such that working fluid molecules become smaller, an electrical attractive force of the working fluid is increased, and an activity of the working fluid is improved. Therefore, a backflow speed of the working fluid at the condensing end of the heat pipe is accelerated, thus improving the thermal transfer efficiency of the heat pipe.

The thermal dissipation system applying the heat pipe structure according to the present invention includes a pipe component, a magnetic means, and a sensing element. The magnetic means is disposed on an external part of the pipe component, and the sensing element is disposed on a heat source, for measuring a working temperature of the heat source. When the working temperature reaches a preset temperature, the magnetic means is driven to generate a magnetic field, so as to magnetize the working fluid in the pipe component, thereby changing the thermal transfer efficiency of the heat pipe according to a practical working temperature of the heat source.

In the heat pipe structure and the thermal dissipation system applying the heat pipe structure according to the present invention, the magnetic field is generated through the magnetic means, so as to magnetize the working fluid in the heat pipe, thereby improving the activity of the working fluid. Therefore, the backflow speed of the working fluid at the condensing end of the heat pipe is accelerated, thus effectively improving the thermal transfer efficiency of the heat pipe.

Features and implementation of the present invention are described in detail with the accompanying drawings and the preferred embodiment.

### BRIEF DESCRIPTION OF THE DRAWINGS

The present invention will become more fully understood from the detailed description given herein below for illustration only, and thus are not limitative of the present invention, and wherein:

FIG. 1 is a schematic view of a heat pipe structure according to the present invention;

FIG. 2 is a schematic view of a magnetic means according to another embodiment of the present invention; and

FIG. 3 is a schematic view of a thermal dissipation system applying the heat pipe structure according to the present invention.

### DETAILED DESCRIPTION OF THE INVENTION

A heat pipe structure and a thermal dissipation system applying the heat pipe structure according to the present invention performs a thermal exchange on a heat source of an electronic device, so as to lower a working temperature of the heat source. The electronic device is a desktop computer, a notebook computer, or other computer systems, and may also be a display card or other expansion interface cards, and the heat source refers to a processing chip performing the operation in the electronic device, for example a CPU or a GPU.

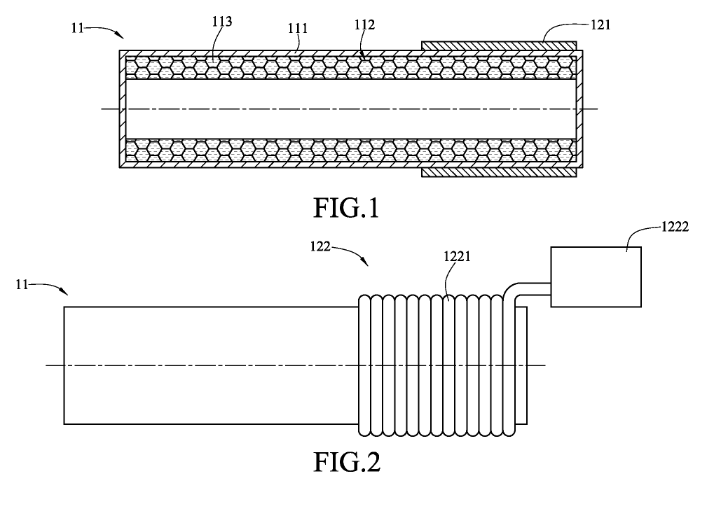

Referring to FIG. 1, the heat pipe structure according to the present invention includes a pipe component 11 and a magnetic means. The pipe component 11 has a sealed elongated pipe body 111 made of copper, aluminum, stainless steel, or other materials. One end of the pipe body 111 is an evaporating end, and the other end is a condensing end. The pipe body 111 includes a capillary structure 112 and a working fluid 113, the capillary structure 112 is formed on an inner wall of the pipe body in a mesh or sinter manner, and the working fluid 113 is one selected from among water, methanol, or other liquids which do not chemically react with the material of the pipe body 111.

The magnetic means is a permanent magnet layer 121 formed by directly coating or sintering ferrite magnetic powder or rare earth metal magnetic powder on an outer surface of the pipe body 111 and magnetizing the outer surface, so as to generate a magnetic field. Alternatively, an exciting device 122 is disposed on the outer surface of the pipe body 111, the exciting device 122 includes a plurality of coils of enameled wire 1221 wound on the outer surface of the pipe body 111. A power source 1222 generates the magnetic field through the enameled wire 1221 (referring to FIG. 2).

In the heat pipe structure according to the present invention, the evaporating end of the pipe component 11 is disposed on a heat source (not shown), and the condensing end may be adhered to a heat sink (not shown). Under a normal state, the working fluid 113 in the pipe component 11 may be gas-liquid phase balanced. When the evaporating end is heated, the working fluid 113 is heated at the evaporating end to quickly become a gas, such that the vapor will quickly flow to the condensing end. When the vapor reaches the condensing end, the vapor is condensed to the liquid because of energy release. Then, the condensed liquid flows back to the evaporation end under a capillary force of the capillary structure 112, so as to form a dynamical balance of the gas-liquid phase transition in the pipe component 11.

The magnetic means generates the magnetic field by the use of the permanent magnet layer 121 or the exciting device 122, the magnetic field magnetizes the working fluid 113 in the pipe component 11, such that molecules of the working fluid 113 become smaller, and an electrical attractive force of the working fluid 113 is increased. Therefore, a backflow speed of the working fluid 113 at the condensing end of the pipe component 11 to the evaporating end is accelerated, thus improving the thermal transfer efficiency of the heat pipe.

The working fluid 113 is, for example, water, and a water molecule is formed by combining two hydrogen atoms with an atomic weight of 1 and one oxygen atom with an atomic weight of 16 through a covalent bond. The water molecule has 10 electrons (5 pairs), in which 1 pair of electrons (internal) is near the oxygen. For the remaining 4 pairs (external), 1 pair of electrons is respectively located between the oxygen nucleus and the hydrogen nucleus, and the rest 2 pairs are lone pairs of electrons, that is, positive charges and negative charges are nonuniformly and asymmetrically distributed, such that the center of the positive charges and the negative charges in the molecule are inconsistent, so as to form a hydrogen bond. The electrical attractive force exists among the water molecules, such that a multi-molecule complex is formed by single molecules, and is called associated water molecule. The electrical attractive force is eliminated or reduced among the multi-molecule complexes. After the water is magnetized, water molecules are rearranged to be ordered, so as to enhance the electrical attractive force of the water molecules. That is to say, the associated water molecule which is not magnetized may be cut into common molecules or relatively smaller associated water molecules under the magnetic force, thereby increasing the electrical attractive force of the water molecules and improving the activity of the water, such that the backflow speed of the working fluid 113 at the condensing end of the pipe component 11 to the evaporating end is accelerated.

Referring to FIGS. 1 and 2, the magnetic means is preferably disposed on the position corresponding to the condensing end of the pipe component 11, so as to accelerate the backflow speed of the working fluid 113 from the condensing end to the evaporating end. However, in the heat pipe structure according to the present invention, the magnetic means is not limited to be disposed on the position corresponding to the condensing end of the pipe component 11, for example, the permanent magnet layer 121 may be coated or sintered on the outer surface of the whole pipe component 11, or the enameled wire 1221 of the exciting device 122 is wound on the outer surface of the whole pipe component 11.

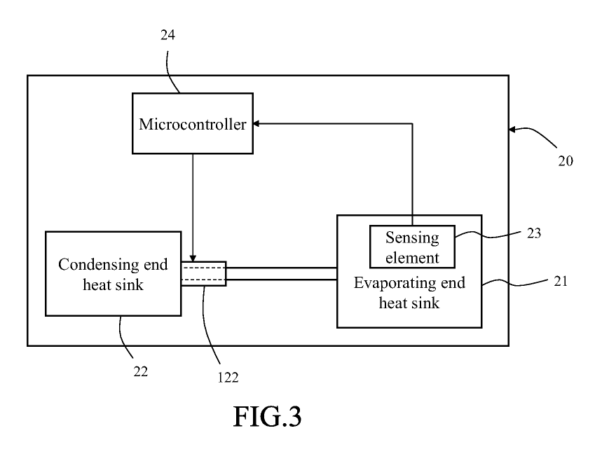

Referring to FIG. 3, the thermal dissipation system applying the heat pipe structure according to the present invention is applicable to dissipate the thermal generated from a heat source (for example CPU, which cannot be shown) of a computer system 20. An evaporating end heat sink 21 is disposed on the heat source, and the evaporating end of the pipe component 11 is adhered to the evaporating end heat sink 21. A condensing end heat sink 22 is disposed on the condensing end of the pipe component 11, and the adopted magnetic means is the exciting device 122, the power source of the exciting device 122 may be an independent power source or a power source (not shown) connected to the computer system 20. A sensing element 23 is disposed on the evaporating end heat sink 21, the sensing element 23 is a temperature sensor, and is electrically connected to a microcontroller 24. The microcontroller 24 is an independent processing chip or the CPU in the computer system 20, and is electrically connected to the exciting device 122, thereby controlling the exciting device 122 to generate the magnetic field or not.

When the computer system 20 begins to operate, the evaporating end heat sink 21 performs a thermal exchange with the thermal generated from the heat source, and conducts the thermal to the evaporating end of the pipe component 11, and the working fluid 113 performs the gas-liquid phase transition in the pipe component 11 to dissipate the heat. If the CPU (heat source) does not perform a large amount of logic operation, the gas-liquid phase transition in the pipe component 11 may meet the demand of the thermal dissipation. If the CPU (heat source) performs a large amount of logic operation, the working temperature of the CPU begins to rise, the sensing element 23 transmits the sensed temperature data to the microcontroller 24, the microcontroller 24 judges that the working temperature exceeds a preset temperature and then controls the power source to supply a current to the exciting device 122, so as to drive the exciting device 122 to generate the magnetic field, and thus the working fluid 113 in the pipe component 11 is magnetized. Similarly, the working fluid 113 is, for example, water, and a water molecule is formed by combining two hydrogen atoms with an atomic weight of 1 and one oxygen atom with an atomic weight of 16 through a covalent bond. The water molecule has 10 electrons (5 pairs), in which 1 pair of electrons (internal part) is near the oxygen, for the remaining 4 pairs (external part), 1 pair of electrons is respectively located between the oxygen nucleus and the hydrogen nucleus, and the remaining 2 pairs are lone pairs of electrons, that is, positive charges and negative charges are nonuniformly and asymmetrically distributed, such that the center of the positive charges and the negative charges in the molecule are inconsistent, so as to form a hydrogen bond. The electrical attractive force exists among the water molecules, such that a multi-molecule complex is formed by single molecules, and is called associated water molecule. The electrical attractive force is eliminated or reduced among the multi-molecule complexes. After the water is magnetized, water molecules are rearranged to be ordered, so as to enhance the electrical attractive force of the water molecule. That is to say, the associated water molecule which is not magnetized may be cut into molecules or relatively smaller associated water molecules under the magnetic force, thereby increasing the electrical attractive force among the water molecules and improving the activity of the water, such that the backflow speed of the working fluid 113 at the condensing end of the pipe component 11 to the evaporating end is accelerated, and the thermal dissipation system may change the thermal transfer efficiency according to the working temperature of the heat source.

What is claimed is:

1. A heat pipe structure, comprising:
a pipe component, having a sealed pipe body, wherein the pipe body comprises a capillary structure and a working fluid, one end of the pipe component is an evaporating end, the other end is a condensing end, and the working fluid performs a gas-liquid phase transition at the evaporating end and the condensing end; and
a magnetic means, disposed on an external part of the pipe component, so as to magnetize the working fluid.

2. The heat pipe structure according to claim 1, wherein the magnetic means is a permanent magnet layer disposed on an outer surface of the pipe component.

3. The heat pipe structure according to claim 1, wherein the magnetic means is an exciting device disposed on an outer surface of the pipe component.

4. The heat pipe structure according to claim 3, wherein the exciting device comprises a power source and a plurality of coils of enameled wire wound on the outer surface of the pipe component.

5. The heat pipe structure according to claim 1, wherein the magnetic means is disposed on a position of the pipe component corresponding to the condensing end.

6. A thermal dissipation system applying a heat pipe structure, applicable to an electronic device to dissipate thermal generated by a heat source in the electronic device, the system comprising:
a heat pipe structure, comprising:
a pipe component, having a sealed pipe body, wherein the pipe body comprises a capillary structure and a working fluid, one end of the pipe component is an evaporating end, the other end is a condensing end, and the working fluid performs a gas-liquid phase transition at the evaporating end and the condensing end; and
an exciting device, disposed on an external part of the pipe component, so as to magnetize the working fluid;
a sensing element, disposed on the heat source, for measuring a working temperature of the heat source; and
a microcontroller, electrically connected to the exciting device and the sensing element, for driving the exciting device to generate a magnetic field according to temperature data measured by the sensing element.

7. The thermal dissipation system according to claim 6, wherein the exciting device comprises a power source and a plurality of coils of enameled wire wound on the outer surface of the pipe component.

8. The thermal dissipation system according to claim 6, wherein the exciting device is disposed on a position of the pipe component corresponding to the condensing end.
